(19) United States
(12) Patent Application Publication
(10) Pub. No.: US 2009/0045501 A1
(43) Pub. Date: Feb. 19, 2009

(54) STRUCTURE ON CHIP PACKAGE TO SUBSTANTIALLY MATCH STIFFNESS OF CHIP

(75) Inventors: Michael A. Gaynes, Vestal, NY (US); David L. Questad, Hopewell Junction, NY (US); Jamil A. Wakil, Wappingers Falls, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/838,474

(22) Filed: Aug. 14, 2007

(51) Int. Cl. H01L 23/48; H01L 21/00

(52) U.S. Cl. 257/693; 438/126; 257/E23.01

(57) ABSTRACT

Chip packages and a related method are disclosed that provide a structure on a side opposite a chip on a carrier of a chip package to substantially match a stiffness of the chip. In one embodiment, a chip package includes a chip coupled to a carrier; and a structure on a side opposite the chip on the carrier, the structure having a first stiffness to substantially match a second stiffness of the chip.

### BACKGROUND

1. Technical Field

The disclosure relates generally to integrated circuit (IC) chip packaging, and more particularly, to chip packages and a related method providing a structure on a side opposite a chip on a carrier of a chip package to substantially match a stiffness of the chip.

2. Background Art

An integrated circuit (IC) chip packaged on an organic carrier is inherently unbalanced mechanically due to the differences in coefficient of thermal expansion (CTE) between the laminate and chip. As shown in FIG. 1, this situation creates a stressed condition under a thermal load in which a module 10, e.g., carrier (laminate) 12, epoxy 14 and/or chip 16, warps. The warping causes severe reliability issues when cyclic thermal loads are introduced, since the structure undergoes cyclic strains. Warping also affects thermal dissipation since attachment of a heat spreader or heat sink to the back of chip 16 becomes very challenging. Attachment of ball grid arrays (BGAs) to a card (under carrier 12) is also made more difficult by the warpage of module 10.

As shown in FIG. 2, one approach to enhance electrical performance in electronic packaging of processors and application specific integrated circuits (ASICs) is to package chip 16 on an organic carrier 12 with decoupling capacitors 20 directly under chip 16 on a backside of carrier 12. As shown in FIG. 2 and the bottom side depiction in FIG. 3, BGAs input/outputs 22 are depopulated in a central region 24. Decoupling capacitors 20 are some form of inter-digitated capacitors (IDCs), typically 5-20, which are reflow soldered on carrier 12 and may also be underfilled with epoxy between the capacitor I/O's.

### SUMMARY

Chip packages and a related method are disclosed that provide a structure on a side opposite a chip on a carrier of a chip package to substantially match a stiffness of the chip. In one embodiment, a chip package includes a chip coupled to a carrier; and a structure on a side opposite the chip on the carrier, the structure having a first stiffness to substantially match a second stiffness of the chip.

A first aspect of the disclosure provides a method comprising: coupling a chip to a carrier; and providing a structure in a central region of a side opposite the chip on the carrier, the structure having a first stiffness substantially matching a second stiffness of the chip.

A second aspect of the disclosure provides a chip package comprising: a chip coupled to a carrier; and a structure on a side opposite the chip on the carrier, the structure having a first stiffness to substantially match a second stiffness of the chip.

A third aspect of the disclosure provides a chip package comprising: a chip coupled to a carrier, the carrier including a ball grid array (BGA) on a side opposite the chip, the BGA being depopulated in a central region of the carrier; and a structure in the central region having a first stiffness that substantially matches a second stiffness of the chip, the structure including a plurality of interdigitated capacitors (IDCs) in the central region, and an epoxy overmolded on the plurality of IDCs, the epoxy with the plurality of IDCs having the first stiffness.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1-3 show conventional chip packages.

FIG. 4 shows a first embodiment of a chip package according to the disclosure.

FIG. 5 shows a second embodiment of a chip package according to the disclosure.

FIG. 6 shows a third embodiment of a chip package according to the disclosure.

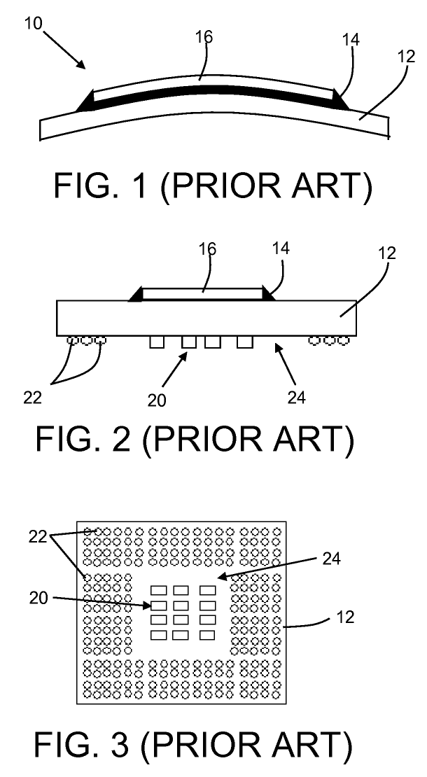

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

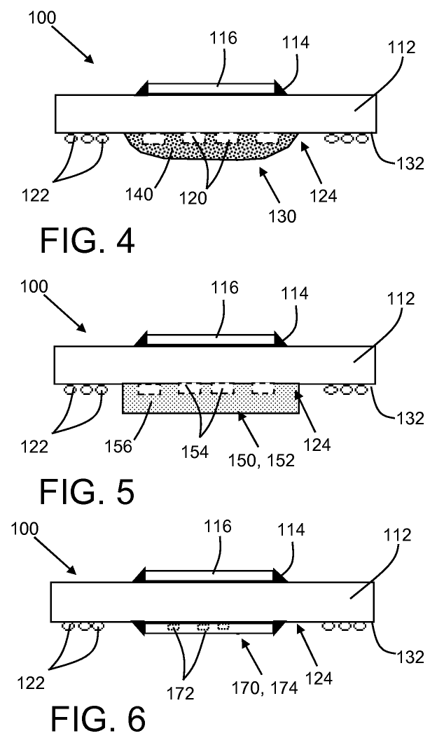

Referring to FIGS. 4-6, chip packages 100 and a related method are disclosed. Chip packages 100 includes a chip 116 coupled to a carrier 112 in any now known or later developed fashion, e.g., C4 joined with underfill epoxy between joints or wire bonded with I/O's on the periphery of the chip and structural adhesive between carrier 112 and chip 116. Chip 116 may include any integrated circuit (IC) chip, and carrier 112 may include any now known or later developed carrier for an IC chip, e.g., a laminate, organic laminate, a plastic, etc.

A structure 130 (FIG. 4), 150 (FIG. 5), 170 (FIG. 6) may be positioned in a central region 124 of a side 132 opposite chip 116 on carrier 112. In one embodiment, central region 124 has been depopulated of ball grid array (BGAs) input/outputs (I/Os) 122. However, BGA I/Os 122 are not necessary to practice the teachings of the disclosure. Structure 130, 150, 170 has a stiffness that substantially matches a stiffness of chip 116. That is, structure 130, 150, 170 has a stiffness that mechanically balances a stiffness of chip 116, thus reducing warping and other related problems. A stiffness of structure 130, 150, 170 may be determined based on a modulus, a coefficient of thermal expansion (CTE) and dimensions of the structure. The constitution of structure 130, 150, 170 may take a variety of forms.

FIG. 4 shows one embodiment of chip package 100 in which structure 130 includes a plurality of interdigitated capacitors (IDCs) 120 in central region 124, and an epoxy 140 overmolded on IDCs 120. Collectively, epoxy 140 and IDCs 120 have a stiffness to match that of chip 116. IDCs 120 may include, for example, reflow soldered joints with underfill between carrier 112 and IDCs 120. Any number of IDCs may be provided, e.g., 5-20. In one embodiment, CTE of IDCs 120 with epoxy 140 is approximately 10 parts per million per degree Celsius (ppm/° C.). However, other CTEs may be employed within the scope of the disclosure. Chip package 100, as shown in FIG. 4, takes advantage of the fact that central region 124 of carrier 112 under chip 116 is typically already depopulated of BGA I/Os 122 and interdigitated capacitors (IDCs) 120 allow different options for creating a chip package 100 that has a balanced or matching stiffness on either side of carrier 112. In this embodiment, IDCs 120 would be formed in central region 124 (using any known manner), and epoxy 140 overmolded on IDCs 120 such that epoxy 140 and IDCs 120 collectively have substantially the same stiffness as chip 116.

FIG. 5 shows a second embodiment of a chip package 100 similar to that of FIG. 4 in which a structure 150 includes a single structure 152 including a plurality of reflowed IDCs 154 in central region 124 encased in a ceramic 156. In this case, single structure 152 has a stiffness substantially matching chip 116. Ceramic 156 may include Alumina or glass ceramic materials. In this embodiment, IDCs 154 would be formed in central region 124 (using any known manner), and ceramic 156 would then be applied to encase IDCs 120. Encasing of IDCs 156 would then occur as part of ceramic curing such that ceramic 156 and IDCs 120 formed a single structure 152 that collectively has substantially the same stiffness as chip 116.

FIG. 6 shows a third embodiment of a chip package 100 in which a structure 170 includes a plurality of IDCs 172 within a capacitor chip 174 that is coupled to central region 124. In this case, capacitor chip 174 has a stiffness substantially matching chip 116. In this embodiment, IDCs 172 would be formed as capacitor chip 174 using any now known or later developed IC fabrication techniques, e.g., material deposition, photolithography, etching, planarization, etc. Capacitor chip 174 may include IDCs 172 formed on a silicon or a ceramic. Capacitor chip 174 would then be coupled to carrier 112 in central region 124 in a conventional fashion, such as C4 attachment of I/Os from chip to carrier or periphery wire bond attachment of I/Os and die attach adhesive between chip 174 and carrier 112.

As shown in FIGS. 4-6, in either embodiment, structure 130, 150, 170 may have different dimensions than chip 116. In this fashion, the dimensions of structure 130, 150, 170 may be customized such that a stiffness thereof substantially matches chip 116. In addition, although structure 130, 150, 170 has been described as in a central region 124 and directly below chip 116, it is within the scope of the disclosure to allow some non-alignment or offset with chip 116 or positioning in a non-central location and still obtain the stiffness balancing/matching.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A method comprising:
coupling a chip to a carrier; and
providing a structure in a central region of a side opposite the chip on the carrier, the structure having a first stiffness substantially matching a second stiffness of the chip.

2. The method of claim 1, wherein the carrier includes a ball grid array (BGA) on the side opposite the chip, the BGA being depopulated in the central region of the carrier.

3. The method of claim 1, wherein the structure providing includes:
forming a plurality of interdigitated capacitors (IDCs) in the central region; and
overmolding the plurality of IDCs with an epoxy, the epoxy and the plurality of IDCs collectively having the first stiffness.

4. The method of claim 3, wherein a coefficient of thermal expansion (CTE) of the plurality of IDCs with the epoxy is approximately 10 parts per million per degree Celsius (ppm/° C.).

5. The method of claim 1, wherein the structure providing includes:
forming a plurality of interdigitated capacitors (IDCs) in the central region;
encasing the plurality of IDCs in a ceramic; and
reflowing the plurality of IDCs within the ceramic to form a single structure,
wherein the single structure has the first stiffness.

6. The method of claim 1, wherein the structure providing includes:
forming a plurality of interdigitated capacitors (IDCs) as a capacitor chip, the capacitor chip having the first stiffness; and
coupling the capacitor chip to the carrier in the central region.

7. The method of claim 6, wherein the capacitor chip includes the plurality of IDCs formed on a silicon or a ceramic.

8. The method of claim 1, wherein the structure has different dimensions than the chip.

9. A chip package comprising:
a chip coupled to a carrier; and
a structure on a side opposite the chip on the carrier, the structure having a first stiffness to substantially match a second stiffness of the chip.

10. The chip package of claim 8, wherein the carrier includes a ball grid array (BGA) on the side opposite the chip, the BGA being depopulated in the central region of the carrier.

11. The chip package of claim 8, wherein the structure includes:
a plurality of interdigitated capacitors (IDCs) in a central region of the side; and
an epoxy overmolded on the plurality of IDCs, the epoxy and the plurality of IDCs collectively having the first stiffness.

12. The chip package of claim 10, wherein a coefficient of thermal expansion (CTE) of the plurality of IDCs with the epoxy is approximately 10 parts per million per degree Celsius (ppm/° C.).

13. The chip package of claim 8, wherein the structure includes:
a single structure including a plurality of reflowed interdigitated capacitors (IDCs) in a central region of the side encased in a ceramic,
wherein the single structure has the first stiffness.

14. The chip package of claim 8, wherein the structure includes:
a plurality of interdigitated capacitors (IDCs) within a capacitor chip that is coupled to a central region of the side, the capacitor chip having the first stiffness.

15. The chip package of claim 14, wherein the capacitor chip includes the plurality of IDCs formed on a silicon or a ceramic.

16. The chip package of claim 8, wherein the structure has different dimensions than the chip.

17. The chip package of claim 8, wherein the first stiffness is determined based on a modulus, a coefficient of thermal expansion (CTE) and dimensions of the structure.

18. A chip package comprising:
a chip coupled to a carrier, the carrier including a ball grid array (BGA) on a side opposite the chip, the BGA being depopulated in a central region of the carrier; and
a structure in the central region having a first stiffness that substantially matches a second stiffness of the chip, the structure including a plurality of interdigitated capacitors (IDCs) in the central region, and an epoxy overmolded on the plurality of IDCs, the epoxy with the plurality of IDCs having the first stiffness.

19. The chip package of claim 18, wherein a coefficient of thermal expansion (CTE) of the plurality of IDCs with the epoxy is approximately 10 parts per million per degree Celsius (ppm/° C.).

20. The chip package of claim 18, wherein the structure does not have the same dimensions as the chip.
